(19) United States
(12) Patent Application Publication
(10) Pub. No.: US 2011/0138902 A1
(43) Pub. Date: Jun. 16, 2011

(54) MEMS MICROPHONE ARRAY ON A CHIP

(75) Inventors: Robert D. White, Medford, MA (US); Joshua S. Krause, Newburyport, MA (US)

(73) Assignee: TUFTS UNIVERSITY, Medford, MA (US)

(21) Appl. No.: 12/994,065

(22) PCT Filed: May 27, 2009
(86) PCT No.: PCT/US09/45289

§ 371 Date: Feb. 28, 2011

Related U.S. Application Data
(60) Provisional application No. 61/056,291, filed on May 27, 2008.

(51) Int. Cl. G01M 9/02; H01L 29/84

(52) U.S. Cl. 73/147; 257/416; 257/E29.324

(57) ABSTRACT

The present invention relates to microelectromechanical systems (MEMS). In particular, the present invention relates to MEMS arrays for use in acoustics and other applications.

### FIELD OF THE INVENTION

The present invention relates to microelectromechanical systems (MEMS). In particular, the present invention relates to MEMS arrays for use in acoustics and other applications.

### BACKGROUND OF THE INVENTION

As aircraft noise regulations become more stringent, the need for modeling and measuring aircraft noise phenomena becomes more important. In order to intelligently design quieter aircraft, the physical mechanisms of noise generation should be understood and any theoretical or computational noise model should be experimentally validated. One validation method is the comparison of the theoretical and measured acoustic far-field pressures. However, single microphone measurements of aeroacoustic sources in wind tunnels are hampered by poor signal to noise ratios that arise from microphone wind self-noise, tunnel system drive noise, reverberation, and electromagnetic interference. In addition, a single microphone cannot distinguish pressure contributions from different source locations. The need for more precise noise source characterization and localization has driven the development of advanced sound field measurement techniques. In particular, the development and application of directional (phased) microphone arrays have been documented as a means to localize and characterize aeroacoustic sources in the presence of high background noise.

Although knowledge of the acoustic field does not uniquely define the source, localization of a source and analyses of the spatial and temporal characteristics of its far-field radiation can provide insight into noise generation mechanisms. Modern acoustic arrays used in wind tunnel studies of airframe noise are typically constructed of moderate numbers (less than or equal to 100) of instrumentation grade condenser microphones, and range in aperture size from several inches to several feet. Data collection, followed by extensive post-processing, has been used to implement various beamforming processes, including conventional beamforming, array shading, shear-layer corrections, adaptive methods, etc. The resulting data files can be over 500 GB in size and require up to an hour of post-processing per data set.

Greater numbers of microphones in an array can improve the ability to characterize a sound field. A greater number of microphones enhances the signal to noise ratio of an array, defined as the array gain, given (in dB) by 10*log(M), where M is the number of microphones. In addition, a large number of microphones may be used to extend the frequency range of an array. The spatial resolution of an array is related to the product kD, where k=ω/c is the acoustic wavenumber, ω is the radian frequency, c is the speed of sound, and D is the aperture size. Thus, a larger aperture is needed to improve the spatial resolution of an array, of most concern at low frequencies. In contrast, the intersensor spacing must be kept less than one-half of the smallest wavelength of interest (highest frequency) to avoid spatial aliasing. The feasibility of scaling the current technology to multiple arrays with large numbers (hundreds or thousands) of microphones is limited by the cost per channel (microphone, amplifier, data acquisition), data handling efficiency (acquisition capabilities, signal processing complexity, storage requirements), and array mobility (size, weight, cabling). In addition, experiments performed in large wind tunnels are costly and require extensive setup. Thus, an array system that provides near real-time output would be advantageous.

Thus, there is a need to develop a new acoustic array system that, among other applications, can be utilized for aeroacoustic measurement.

### SUMMARY OF THE INVENTION

The present invention relates to microelectromechanical systems (MEMS). In particular, the present invention relates to MEMS arrays for use in acoustics and other applications.

For example, in some embodiments, the present invention provides a composition comprising an array of MEMS microphones (e.g., comprising at least 10, at least 64, preferably at least 100, and even more preferably at least 1000 MEMS microphones on a single chip). In some embodiments, each of the MEMS microphones is between approximately 10 μm and 1000 μm in diameter (e.g., approximately 600 μm). In some embodiments, the array has a center to center pitch of between approximately 0.5 and 1.5 mm (e.g., between approximately 1.2625 mm). In some embodiments, the MEMS microphones comprise a silicon substrate with one or more coating layers. In some embodiments, the coating layers comprise one or more layers (e.g., including, but not limited to, nitride layers, polysilicon polymer layers, metal layers, anchor layers, poly-para-xylylene (parylene) layers, and dimple layers). In some embodiments, the array is coated in parylene. In some embodiments, the dimple layer comprises corrugated circles. In some embodiments, one or more of the layers comprise holes. In some embodiments, the array comprises electronic components (e.g., located off of said array chip). In some embodiments, the array comprises guard bands. In some embodiments, the array comprises alignment markers. In some embodiments, the array comprises front venting. In some embodiments, the composition comprises a plurality of array chips assembled end to end.

The present invention further provides a method of measuring pressure fluctuations, comprising: contacting a device, comprising an array of MEMS microphones (e.g., comprising at least 10, at least 64, preferably at least 100, and even more preferably at least 1000 MEMS microphones on a single chip) with a turbulent boundary layer under conditions such that the device measures pressure fluctuations below the turbulent boundary layer. In some embodiments, the device is located on an aircraft in flight or in a wind tunnel.

### DESCRIPTION OF THE FIGURES

FIG. 1 shows layers of exemplary MEMS devices of the present invention.

FIG. 2 shows a CAD drawing of a complete sensor array.

FIG. 3 shows a CAD drawing of wire connections in between elements

FIG. 4 shows a schematic of an individual element of exemplary MEMS devices of the present invention.

FIG. 5 shows alignment markers for post processing of exemplary MEMS devices of the present invention.

FIG. 6 shows an acoustic circuit diagram of a pressure sensor element.

FIG. 7 shows center displacement and displacement relative to pressure angle versus frequency.

FIG. 8 shows predicted sensitivity and voltage relative to pressure versus frequency for a single array element.

FIG. 9 shows a cross section of a diaphragm of exemplary MEMS devices of the present invention.

FIG. 10 shows a cross section of wire connections of exemplary MEMS devices of the present invention.

FIG. 11 shows a cross section of pad connections of exemplary MEMS devices of the present invention.

FIG. 12 shows pin output for each element including ground connection of exemplary MEMS devices of the present invention. Also depicted is the flow direction, pitch in both X and Y directions and fabricated chip size.

FIG. 13 shows a scanning electron microscope image of vent hole shape and size.

FIG. 14 shows a photograph of two completed microphone arrays. MEMS fabrication, release, wirebonding, coating in Parylene-C, and epoxy are included.

FIG. 15 shows a photograph illustrating the wirebond connections from the MEMS device to the ceramic pin grid array package.

FIG. 16 shows a CAD rendered drawing of package and spacing elements to place the MEMS device in the center and flush with the top of the packaging. These features allow for the reduction of flow alterations over the device and package.

FIG. 17 shows a photograph of an exemplary array.

FIG. 18 shows a lumped element model (LEM) for diaphragm displacement and sensitivity output per unit pressure.

FIG. 19 shows sensitivity model predictions for one element in the array with variations in vent hole size demonstrating importance of reduced vent hole sizes.

FIG. 20 shows sensitivity versus bias curve showing linearity of MEMS device with increase in bias. The Figure shows that MEMS device responds to acoustic signal rather than electromagnetic interference.

FIG. 21 shows 14 Elements in the MEMS array vs theory after parylene-C deposition.

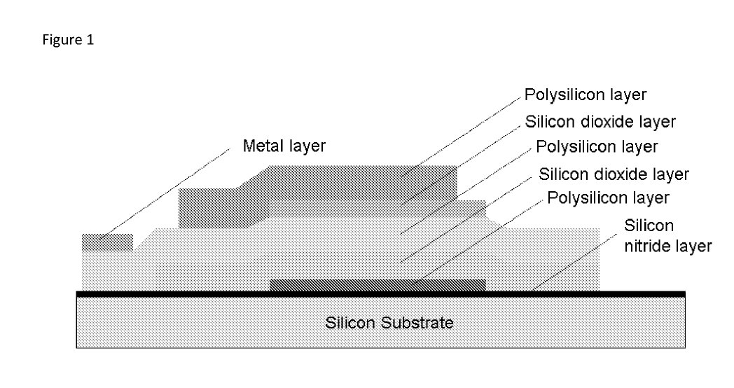

### DETAILED DESCRIPTION

In some embodiments, the present invention provides a surface micromachined microphone array for characterization of pressure fluctuations below the turbulent boundary layer (TBL). At relatively high Reynolds numbers based on the momentum boundary layer thickness (Re>4000), the features in the TBL are on the order of 50 microns (Lofdahl and Gad-el-Hak, Progress in Aerospace Sciences, 1999. 35(2): p. 101-203). Therefore, it is difficult to characterize the details of the flow with conventional millimeter to centimeter scale sensors. By moving to MEMS sensor arrays, the present invention provides compositions and methods for assaying the microscale eddy currents, which allow for the characterization of higher wavenumber features and high frequency temporal features of in-flight TBLs. This increase in spatial and temporal resolution provides valuable characterization data of the TBL, which leads to the reduction of unwanted noise in airplane cabins.

TBL pressure couples into the fuselage structure and propagates into the cabin. By better understanding the structure of the TBL, particularly its frequency-wavenumber spectra, the acoustic attenuation occurring through the fuselage wall can be improved.

The design, fabrication, and characterization of a surface micromachined, front-vented, dense (e.g., 64 channel (8×8)), capacitively sensed pressure sensor array was developed during experiments conducted in some embodiments of the present invention and is described below. The array was fabricated using the MEMSCAP PolyMUMPS process, a three layer polysilicon surface micromachining process. An acoustic lumped element circuit model was used to design the system. This non-limiting, illustrative embodiments of the invention demonstrates advantages of this design approach. The experimental data show single element acoustic sensitivity (as a function of frequency) increasing from 0.1 mV/Pa at 700 Hz to 3 mV/Pa at 7 kHz. A laser Doppler velocimetry (LDV) system was used to map the spatial motion of the elements in response to electrostatic excitation. A strong resonance at 480 kHz is the first primary mode. The system had a bandwidth of approximately 7 to 500 kHz.

Other MEMS microphones (See e.g., Royer et al., Sensors and Actuators, 1983. 4: p. 357-362; Scheeper et al., Journal of Microelectromechanical Systems, 1992. 1(3): 147-154; Lofdahl and Gad-el-Hak, Progress in Aerospace Sciences, 1999. 35(2): p. 101-203; Lofdahl and Gad-el-Hak, Measurement Science and Technology, 1999. 10: p. 665-686; Bai and Huang, Journal of Acoustical Society of America, 2004. 116(1): p. 303-312) do not provide the fully surface micromachined array of the present invention or a microphone array on a single chip with a fine center-to-center pitch, and front venting. In exemplary experiments conducted during the course of development of the present invention, the pressure sensor array had a center-to-center pitch of 1.2625 mm with a membrane diameter of 600 microns. Due to this, high resolution data on the frequency wavenumber spectra of the TBL experienced by an aircraft in flight is provided by the arrays of the present invention. Also, by assembling the array chips end-to-end, the arrays of the present invention are able to determine low wavenumber information through the larger spatial scale.

### I. Microelectromechanical System

MEMS technology can be implemented using a number of different materials and manufacturing techniques; the choice of which depends on the device being created and the market sector in which it has to operate. The present invention is not limited to particular MEMS manufacturing methods. Exemplary methods are described herein.

### A. Materials

In some embodiments, silicon is used to fabricate MEMS systems. Silicon is the material used to create most integrated circuits used in consumer electronics in the modern world. The economies of scale, ready availability of cheap high-quality materials and ability to incorporate electronic functionality make silicon attractive for a wide variety of MEMS applications. Silicon also has significant advantages engendered through its material properties. In single crystal form, silicon is an almost perfect Hookean material, meaning that when it is flexed there is virtually no hysteresis and hence almost no energy dissipation. As well as making for highly repeatable motion, this also makes silicon very reliable as it suffers very little fatigue and can have service lifetimes in the range of billions to trillions of cycles without breaking. The basic techniques for producing silicon based MEMS devices are deposition of material layers, patterning of these layers by photolithography and then etching to produce the required shapes.

In other embodiments, MEMS systems are fabricated from polymers. MEMS devices can be made from polymers by processes such as injection moulding, embossing or stereolithography.

In still further embodiments, metals are used to create MEMS elements. Metals can be deposited by electroplating, evaporation, and sputtering processes. Commonly used metals include, but are not limited to, gold, nickel, aluminum, chromium, titanium, tungsten, platinum, and silver.

### B. Manufacturing Processes

The present invention is not limited to a particular deposition process. Examples of deposition processes include, but are not limited to, electroplating, sputter deposition, physical vapour deposition (PVD) and chemical vapour deposition (CVD).

In some embodiments, photolithography is used in generating MEMS devices. Lithography in MEMS context is typically the transfer of a pattern to a photosensitive material by selective exposure to a radiation source such as light. A photosensitive material is a material that experiences a change in its physical properties when exposed to a radiation source. If a photosensitive material is selectively exposed to radiation (e.g. by masking some of the radiation) the pattern of the radiation on the material is transferred to the material exposed, as the properties of the exposed and unexposed regions differs.

This exposed region can then be removed or treated providing a mask for the underlying substrate. Photolithography is typically used with metal or other thin film deposition, wet and dry etching.

In some embodiments, following deposition, etching processes are used to generate MEMS devices. There are two basic categories of etching processes: wet and dry etching. In the former, the material is dissolved when immersed in a chemical solution. In the latter, the material is sputtered or dissolved using reactive ions or a vapor phase etchant.

In some embodiments, wet chemical etching is utilized. Wet chemical etching utilizes a selective removal of material by dipping a substrate into a solution that can dissolve it. Due to the chemical nature of this etching process, a good selectivity can often be obtained, which means that the etching rate of the target material is considerably higher than that of the mask material if selected carefully.

Some single crystal materials, such as silicon, have different etching rates depending on the crystallographic orientation of the substrate. This is known as anisotropic etching and one of the most common examples is the etching of silicon in KOH (potassium hydroxide), where Si <111> planes etch approximately 100 times slower than other planes (crystallographic orientations). Therefore, etching a rectangular hole in a (100)-Si wafer will result in a pyramid shaped etch pit with 54.7° walls, instead of a hole with curved sidewalls as it would be the case for isotropic etching, where etching progresses at the same speed in all directions. Long and narrow holes in a mask will produce v-shaped grooves in the silicon. The surface of these grooves can be atomically smooth if the etch is carried out correctly, with dimensions and angles being extremely accurate.

In some embodiments, electrochemical etching is utilized. Electrochemical etching (ECE) for dopant-selective removal of silicon is one exemplary method to automate and control etching. An active p-n diode junction is used, and either type of dopant can be the etch-resistant (“etch-stop”) material. Boron is one etch-stop dopant. In combination with wet anisotropic etching as described above, ECE has been used successfully for controlling silicon diaphragm thickness in commercial piezoresistive silicon pressure sensors. Selectively doped regions can be created either by implantation, diffusion, or epitaxial deposition of silicon.

In other embodiments, reactive ion etching is utilized. In reactive ion etching (RIE), the substrate is placed inside a reactor in which several gases are introduced. A plasma is struck in the gas mixture using an RF power source, breaking the gas molecules into ions. The ions are accelerated towards, and react with, the surface of the material being etched, forming another gaseous material. This is known as the chemical part of reactive ion etching. There is also a physical part which is similar in nature to the sputtering deposition process. If the ions have high enough energy, they can knock atoms out of the material to be etched without a chemical reaction. It is a very complex task to develop dry etch processes that balance chemical and physical etching, since there are many parameters to adjust. By changing the balance it is possible to influence the anisotropy of the etching, since the chemical part is isotropic and the physical part highly anisotropic the combination can form sidewalls that have shapes from rounded to vertical.

In yet other embodiments, deep reactive etching is utilized. Deep reactive ion etching is a subclass of RIE. In this process, etch depths of hundreds of micrometres can be achieved with almost vertical sidewalls. Currently there are two variations of the DRIE. The first variation consists of three distinct steps (the Bosch Process as used in the UNAXIS tool) while the second variation only consists of two steps (ASE used in the STS tool). In the 1st Variation, the etch cycle is as follows: (i) SF6 isotropic etch; (ii) C4F8 passivation; (iii) SF6 anisoptropic etch for floor cleaning In the 2nd variation, steps (i) and (iii) are combined.

Both variations operate similarly. The C4F8 creates a polymer on the surface of the substrate, and the second gas composition (SF6 and O2) etches the substrate. The polymer is immediately sputtered away by the physical part of the etching, but only on the horizontal surfaces and not the sidewalls. Since the polymer only dissolves very slowly in the chemical part of the etching, it builds up on the sidewalls and protects them from etching. As a result, etching aspect ratios of 50 to 1 can be achieved. The process can easily be used to etch completely through a silicon substrate, and etch rates are 3-6 times higher than wet etching.

In still further embodiments, xenon diflouride etching is utilized. Xenon difluoride (XeF2) is a dry vapor phase isotropic etch for silicon. Primarily used for releasing metal and dielectric structures by undercutting silicon, XeF2 has the advantage of a stiction-free release. Its etch selectivity to silicon is very high, allowing it to work with photoresist, SiO2, silicon nitride, and various metals for masking. Its reaction to silicon is “plasmaless”, is purely chemical and spontaneous and is often operated in pulsed mode.

### C. Micromachining

In some embodiments, machining is done via bulk micromachining. The whole thickness of a silicon wafer is used for building the micro-mechanical structures. Silicon is machined using various etching processes. Anodic bonding of glass plates or additional silicon wafers is used for adding features in the third dimension and for hermetic encapsulation. Bulk micromachining has been used in enabling high performance pressure sensors and accelerometers that have changed the shape of the sensor industry in the 80's and 90's.

In other embodiments, surface micromachining is utilized. Surface micromachining uses layers deposited on the surface of a substrate as the structural materials, rather than using the substrate itself. Surface micromachining was created in the late 80's to render micromachining of silicon more compatible with planar integrated circuit technology, with the goal of combining MEMS and integrated circuits on the same silicon wafer. The original surface micromachining concept was based on thin polycrystalline silicon layers patterned as movable mechanical structures and released by sacrificial etching of the underlaying oxide layer. Interdigital comb electrodes were used to produce in-plane forces and to detect in-plane movement capacitively.

In still further embodiments, high aspect ratio (HAR) micromachining is utilized. While it is common in surface micromachining to have structural layer thickness in the range of 2 μm, in HAR micromachining the thickness is from 10 to 100 μm. The materials commonly used in HAR micromachining are thick polycrystalline silicon, known as epi-poly, and bonded silicon-on-insulator (SOI) wafers although processes for bulk silicon wafer also have been created (SCREAM). Bonding a second wafer by glass frit bonding, anodic bonding or alloy bonding is used to protect the MEMS structures.

### II. MEMS Microphone Arrays

As described above, in some embodiments, the present invention provides arrays of MEMS microphones. In some embodiments, each microphone comprises a silicon substrate with a nitride layer, one or more polysilicon layers, a metal layer, and a polymer layer. In some embodiments, the MEMS devices further include sacrificial layers (e.g., silicon dioxide layers with etched anchors and a dimple layer). In some embodiments, the dimple layer comprises corrugated circles. In some embodiments, one or more of the layers comprise holes. In some embodiments, microphones comprise a poly-para-xylylene (parylen) layer. This layer serves to reduce vent hole size, provide a moisture barrier and electrically isolate the array from the environment and itself. In some embodiments, MEMS microphones are manufactured using a fully surface micromachined foundry process.

In some embodiments, each MEMS element is approximately 10-100 μm in diameter. In other embodiments, each element is larger than 100 μm in diameter (e.g., 100-1000 μm in diameter or approximately 600 μm in diameter). In some embodiments, the arrays have a fine center to center pitch (e.g., approximately 1 mm (e.g., 0.5 to 1.5 mm, 0.8 to 1.3 mm, or approximately 1.2625 mm)).

The arrays of embodiments of the present invention provide high density arrays. For example, in some embodiments, arrays comprise a plurality (e.g., at least 10 sensors, at least 50 sensors, at least 100 sensors, at least 500 sensors, or at least 1000 sensors) or sensors located on a single chip. In some embodiments, each chip further comprises electronics. In other embodiments, the electronics are off chip in order to optimize signal from the high density arrays. In some embodiments, arrays comprise guard bands (e.g., located in between each wire) to reduce cross talk between microphones. In some embodiments, the arrays comprise ground connectors (e.g., to disperse static discharges, EMI and RFI signals). In some embodiments, the arrays comprise alignment markers. In some embodiments, the array chip comprises front venting.

In some embodiments, multiple array chips are assembled end to end. For example, in some applications, 2 or more, 5 or more, 10 or more, 50 or more, or 100 or more array chips are utilized.

The present invention further provides systems comprising the MEMS microphone arrays described herein. In some embodiments, in addition to the MEMS microphone arrays, systems comprise computer components to collect, store and analyze data, and any other component useful, sufficient, or necessary to use of the arrays.

### III. Applications

The MEMS microphone arrays of embodiments of the present invention find use in a variety of applications. Exemplary applications are described below.

### A. Aeronautics

In some embodiments, the MEMS microphone arrays of embodiments of the present invention find use in aeronautics applications. In some embodiments, the present invention provides methods and compositions for characterizing pressure fluctuation (e.g., below the turbulent boundary layer) of aircraft in flight. The arrays of embodiments of the present invention provide high resolution data on the frequency wavenumber spectra of the TBL experienced by an aircraft in flight. The arrays further provide low wavenumber information through the larger spatial scale. In some embodiments, the resulting data is used to optimize aircraft construction to reduce vibrations and cabin noise.

### B. Other Applications

The present invention is not limited to aeronautics applications. The sensor arrays of the present invention find use in a variety of additional applications. Exemplary applications include, but are not limited to, hearing aids, microphones for commercial electronics (e.g., cellular phones, computers, etc.), acoustic holography, and laboratory and field characterization of acoustic pressure fields in automotive, industrial, and military environments.

### EXPERIMENTAL

The following examples are provided in order to demonstrate and further illustrate certain preferred embodiments and aspects of the present invention and are not to be construed as limiting the scope thereof.

### Example 1

### MEMS Arrays

### Overview of Exemplary Design

The exemplary design comprises 10 layers including the silicon substrate:

### Structural Layers:

Silicon Wafer

Nitride Layer

Poly 0 Layer

Poly 1 Layer

Poly 2 Layer

Metal Layer

### Sacrificial Layers

Anchor 1 Layer

Anchor 2 Layer

Poly1_Poly2_Via Layer

Dimple Layer

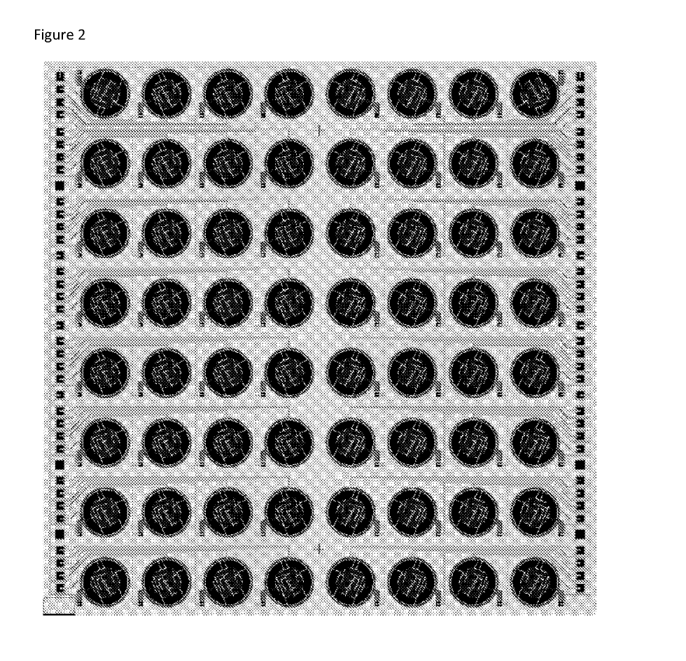

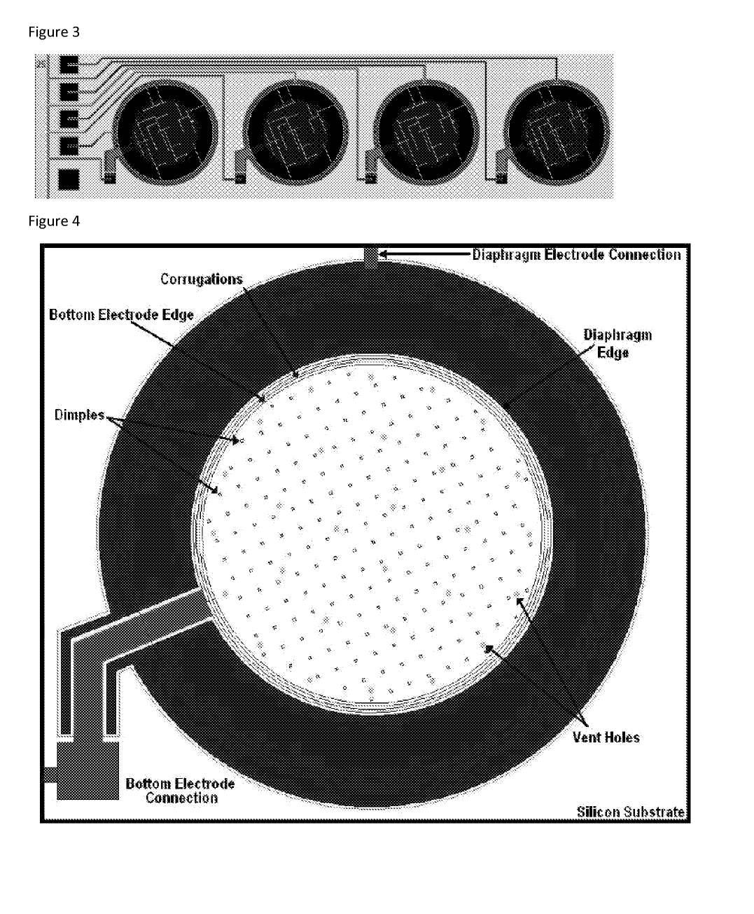

The exemplary design implements guard bands to reduce crosstalk between channels, alignment markers (shown in FIG. 5) for post processing, and extra ground connections to ensure a safe dissipation of static discharges, EMI and RFI signals. A uniform process was applied to the wiring of each element with guard bands located in between each wire (where each guard band connects to a common ground). A sample of this can be viewed below in FIG. 3. The wiring pattern can be viewed in FIG. 2 above. At the top of the sensor array the wiring is in a dense pattern to fit in all the connections and still comply with the design rule constraints (as well as keep the correct pitch to align sensors next to each other).

The design for each sensor comprises the base silicon wafer, followed by a nitride layer. The first structural layer to compose the actual sensor element is the Poly 0 layer. The Poly 0 layer is a circle with a radius of 290 μm which acts as the bottom electrode for the microphone. Poly 0 is also used to “tunnel” under the diaphragm supports (using an oxide as insulation) to create the electrical connection between the bottom electrode and the wire which leads to the common grounding pads.

The Dimple layer is next used to etch part of the way through the oxide 1 layer. This is used to put in place “dimples” on the bottom of the poly 1 layer which will minimize the adhesion problems associated with stiction during release at the end of the fabrication process. Through the use of the peel number the number of dimples associated with reducing stiction are spaced 30 μm apart for a total of 201 dimples over the Poly 1 region (calculations shown below). Besides the dimples to prevent adhesion, there are two-five micron corrugated tori shaped concentric circles using the Dimple Layer which allow for the partial relaxation of any residual stresses produced in the diaphragm during the fabrication process or during operation.

Description of polyMUMPS Process Layers

The first sacrificial layer (oxide 1, 2 μm thick) was patterned using “Anchor 1”. This was drawn 10 microns around the Poly 0 layer in a torus shape. The Anchor 1 layer defines the inner dimension of the diaphragm, giving the mechanical diaphragm an inner radius of 300 μm. Anchor 1 was also used to anchor the polysilicon/metal signal wires, guard bands, pads, and ground connections.

Following the Anchor 1 layer, the Poly1 layer was patterned. The Poly1 layer is used both as the first part of the mechanical diaphragm and as part of the poly/metal wires. The Poly1 portion of the diaphragm has a radius of 455 μm, extending well into the Anchor region. The next layer fabricated in the process is the Poly1 Poly2 Via layer which opens holes from the Poly1 to Poly2 layers. Due to the constraints of the bulk processing in the MUMPS process, the two layers (Poly1 and Poly2) were combined to create a structure with a 3.5 μm thickness. The Poly1 Poly2 Via layer is used for this purpose; it removes the interlayer dielectric (oxide 2) so that Poly 1 and Poly 2 are directly in contact, effectively forming a single 3.5 μm thick polysilicon structural layer.

The Anchor 2 layer opens holes for poly 2 directly to the Nitride or Poly0 layer. In this application the Anchor 2 is solely used to ground the elements to the substrate. Holes are etched through both the poly 1 and poly 2 layers using the “hole 1” and “poly 2” layers. The hole through poly 1 is 6 μm in diameter; the hole through poly 2 is 4 μm in diameter. The holes have two purposes: (1) they are used to introduce HF etchant during release to etch out the oxide 1 sacrificial layer (2) they act as frontside “vents” during operation, equalizing ambient pressure with gap pressure and providing damping.

Finally, the Metal layer is used as a routing layer and as electrical pads around the outside of the device. All the wires and pads are combinations of polysilicon and metal, anchored directly to the nitride layer or to the bulk silicon, as appropriate.

### Modeling

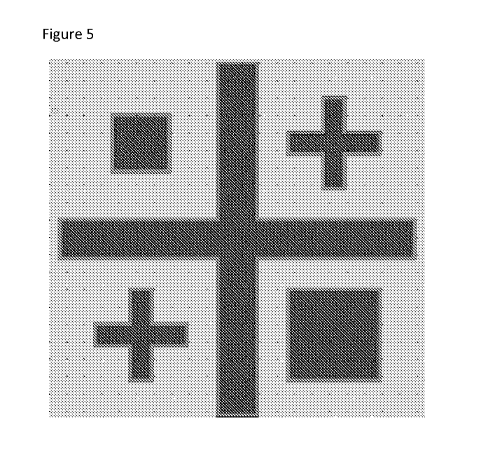

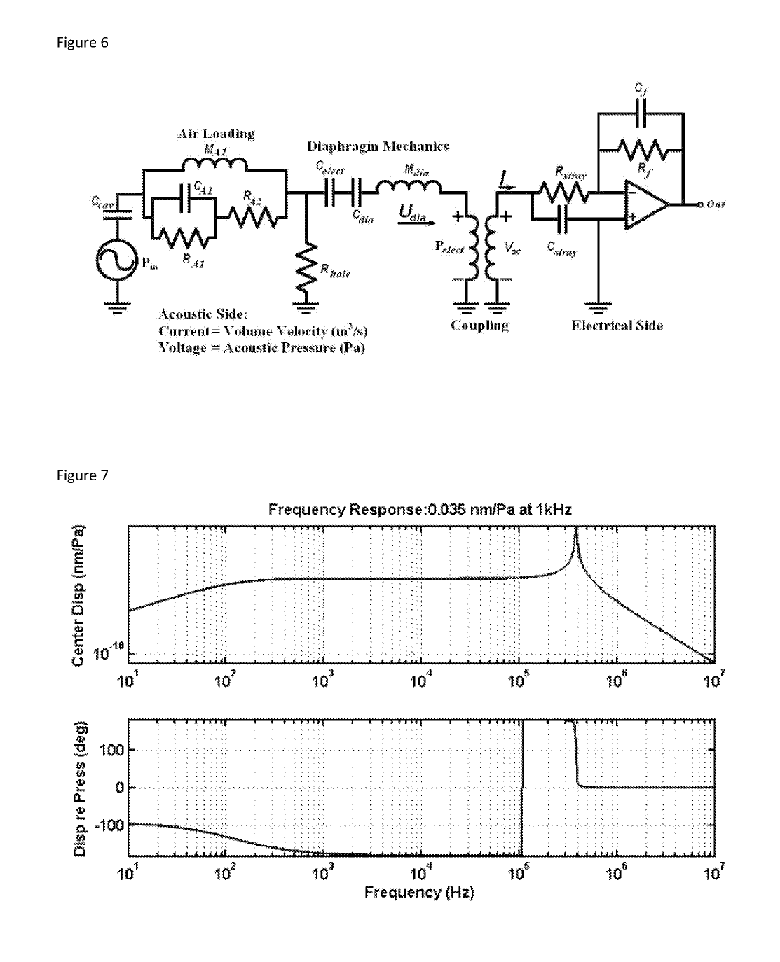

For each element in the design, a MATLAB script was compiled to examine the response of the pressure sensor (the single element design can be seen in FIG. 4 below). The parameters were computed following an acoustic circuit diagram shown in FIG. 4. The compliance, resistance and masses were accounted for in the circuit diagram and then implemented into the MATLAB script. The values of each parameter were computed using computational values for microphones from the text Acoustics by Leo L. Beranek and Fundamentals of Acoustics, Fourth Edition by Kinsler et al. The calculations for each parameter are:

$$\begin{matrix}{R}_{A 1} = \frac{0.1404 ρ c}{{a}_{eff}^{2}} , & ( 1 ) \\ {R}_{A 2} = \frac{ρ c}{π {a}_{eff}^{2}} , & ( 2 ) \\ {M}_{A 1} = \frac{8 ρ}{3 {π}^{2} {a}_{eff}} , & ( 3 ) \\ {C}_{A 1} = \frac{5.94 {a}_{eff}^{3}}{ρ {c}^{2}} , & ( 4 ) \\ {C}_{cav} = \frac{{V}_{gap}}{ρ {c}^{2}} , & ( 5 ) \\ {C}_{dia} = \frac{π {a}^{6} ( 1 - {v}^{2} )}{16 {Et}_{dia}^{2}} , & ( 6 ) \\ {M}_{dia} = \frac{9 ρ {t}_{dia}}{5 π {a}^{2}} , & ( 7 ) \\ {R}_{through} = \frac{72 μ {t}_{dia}}{n π {a}_{hole}^{4}} , & ( 8 ) \\ S = \frac{π {a}_{hole}^{2}}{{C}^{2}} , & ( 9 ) \\ {C}_{f} = \frac{S}{2} - \frac{{S}^{2}}{8 - \frac{1}{4} ln ( S ) - \frac{3}{8}} , & ( 10 ) \\ {R}_{squeeze} = \frac{12 μ {C}_{f}}{n π {t}_{gap}^{3}} , & ( 11 ) \\ {R}_{hole} = {R}_{squeeze} + {R}_{through} , & ( 12 ) \\ N = \frac{{V}_{bias} ε}{{t}_{gap}^{2}} & ( 13 )\end{matrix}$$

### Where:

R_{A1}, R_{A2}, C_{A1}, and M_{A1} together capture the radiation impedance of the external air
V_{gap} is the volume of the gap in between the diaphragm and bottom of the cavity
C_{cay} is the cavity compliance of the gap
R_{through} is the resistance to air flow through the holes in the poly 1 and 2 layers
R_{squeeze} is the resistance to air flow in the air gap behind the diaphragm
Rₕₒₗₑ is the equivalent resistance of the combination of R_{through} and R_{squeeze}
C_{dia} is the compliance for the diaphragm
M_{dia} is the mass of the diaphragm.
ρ is the density of the air, except in the computation of M_{dia} where it is the density of the diaphragm material
a is the radius of the diaphragm
a_{eff} is the effective radius of the diaphragm for computation of the external air impedance (a_{eff}=0.8a)
ω is the operating frequency
c is the speed of sound in air
t_{gap} is the thickness of the air gap behind the diaphragm
n is number of holes in the diaphragm (Poly 1 and Poly 2 layers)
μ is the viscosity of the air
t_{dia} is the thickness of the diaphragm
aₕₒₗₑ is the vent/etch hole radius in the diaphragm
C is the center to center spacing of the holes in the diaphragm
E is the elastic modulus of the diaphragm
ν is the Poisson ratio of the diaphragm
N is the coupling parameter for the ideal transformer representing coupling between the mechanical and electrical domains
V_{bias} is the applied DC bias
ε is the permittivity of free space

Using these parameters, along with an accompanying circuit model, a MATLAB script was completed. The final analysis contained two m-files to which the microphone was modeled.

A file was used to model the diaphragm as a circular plate with uniform load. The code contained the acoustic properties of the medium, geometric and electrical properties of the design, and material properties and dimensions of the PolyMUMPS layers. Ensuing the initial setup of the variables and constants, the response of the membrane was calculated to achieve the total volume velocity of the membrane (μm³/s) in response to one mega-Pascal of pressure input, the center point displacement (μm/Pa), and the voltage output (V/Pa). To achieve the outputs, a for loop from the first frequency to the total number of frequencies analyzed in the entire script was implemented. Following, Equations 1-13 were defined in the MATLAB code to find the final output.

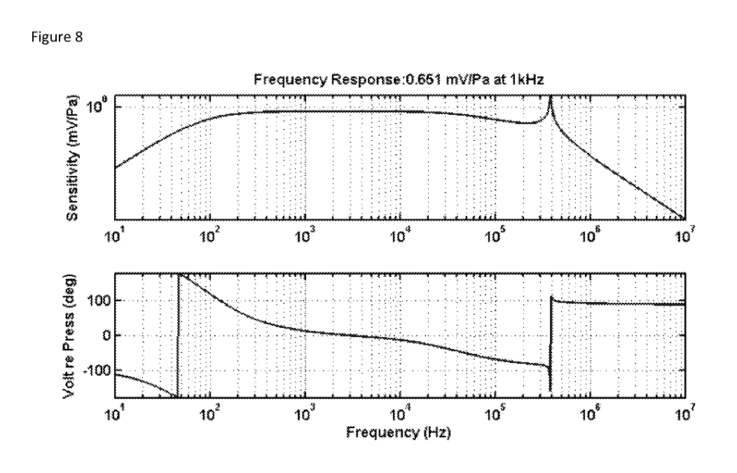

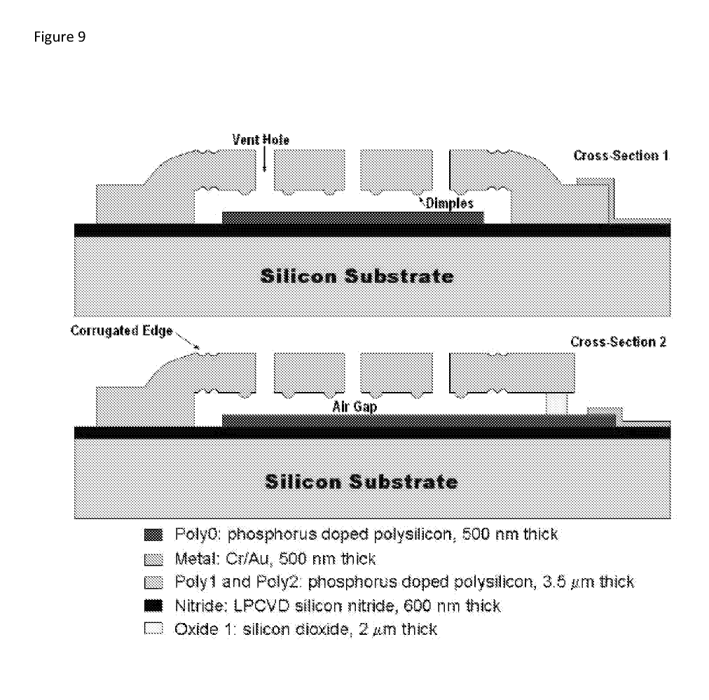

After computing all the acoustic elements in the acoustic circuit model, the impedances of each component of the model were analyzed. From these values one can determine the response of the membrane. The total volume velocity of the membrane (μm³/s) in response to one mega-Pascal of pressure input, the center point displacement (μm/Pa), and the voltage output (V/Pa) were obtained and plotted in four graphs (shown in FIGS. 7 and 8). Using the data obtained through the MATLAB scripts, array characteristics, such as sensitivity of each element (0.65 mV/Pa at gain stage output), which can be used to calculate the sensitivity for the entire array (41.7 mV/Pa at gain stage output), phase information for voltage relative to pressure, center point displacement (0.035 nm/Pa), and phase information for displacement relative to pressure were calculated. From the values referenced using the plots of the frequency response, the sensitivity of the entire array, the individual element dynamic range, In-phase array dynamic range, total sensor bandwidth, and low frequency resonance were calculated.

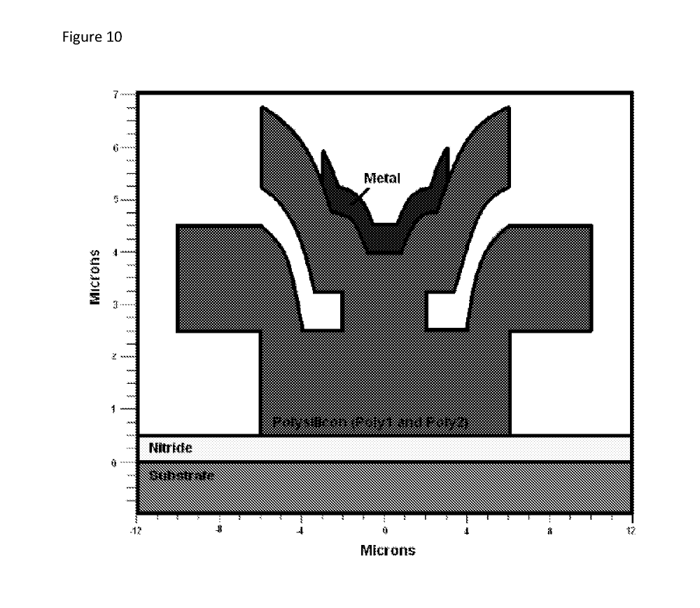

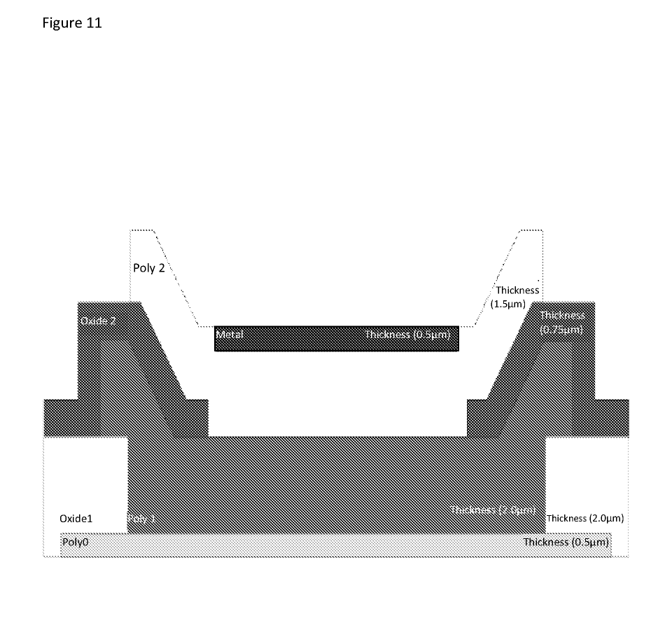

The resistance, stray capacitance and interference due to radio frequency and electromagnetic interfence are the major concerns for wiring in the acoustic array. Providing a strong conducting path is vital in the MEMS process. The polysilicon layers are highly doped and provide low resistivities, but the metal layer still provides a much lower resistance. The cross sectional drawing of a wire in the array is shown in FIG. 10. The resistance and capacitance are calculated for longest trace connection. The resistances and capacitances for all wires are located in Table 2. The wires are connected to a set of electrical pads to which each of the connections are located in Table 3 for each pin output (76 pad connections are used to connect to the 64 elements and 12 are used as grounding pads). The cross sectional drawing can be viewed in FIG. 11 and depicts a standard pad in the PolyMUMPS process. A similar approach was used in the element design and can be seen in FIG. 4 through the via connection attached to the element. The via is attached through a tunneling method from the diaphragm. The tunnel for each element uses the Poly 0 layer as the electrical connection, and oxide 1 as an insulator. Using the tunnel and via, each bottom electrode has a metal wire electrical connection to a ground pad but also uses a via to the backside silicon. The end of the via uses both the anchor 1 and anchor 2 layer to connect directly to the silicon substrate. These anchor layers allow for the nitride layer to be removed and create one common ground (the bulk silicon).

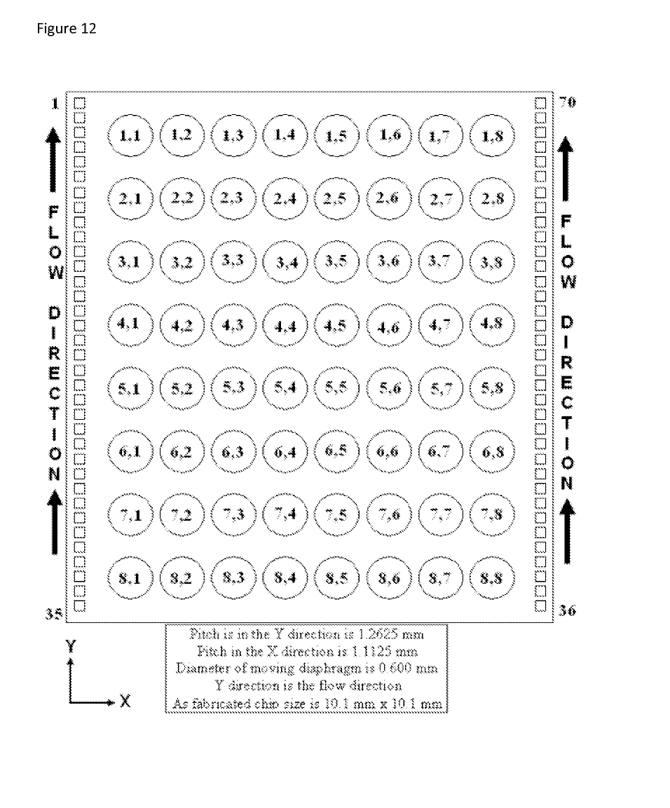

Finally, the overall spacing was optimized. FIG. 12 shows the final array shape and design with corresponding element placement. The element/pin placement can be found in Table 3. The dimensions of the exemplary design are calculated by the overall chip size of 1.01 cm×1.01 cm. The pitch is 1.2625 mm in the Y direction, whereas the spacing in the X direction is 1.1125 mm for each element due to the electrical connections needed. The electrical connections are wire bonded in the X direction to reduce the effect on the flow in the Y direction where the sensors are tested.

TABLE 2
Wire resistance summary.

| | | Resistance (Ω/□) | | |
|---|---|---|---|---|
| Material | Width (μm) | Minimum | Maximum | Nominal |
| Poly 1 | 20 | 1 | 20 | 10 |
| Poly 2 | 12 | 10 | 30 | 20 |
| Metal | 6 | 0.05 | 0.07 | 0.06 |

| Trace | Length (μm) |
|---|---|
| wₛₕₒᵣₜₑₛₜ | 437.072 |
| w_{longest} | 4382.582 |
| w_{middle1} | 3273.302 |
| w_{middle2} | 2186.639 |

Trace Resistances (Ω)

| wₛₕₒᵣₜₑₛₜ | w_{longest} | w_{middle1} | w_{middle2} |
|---|---|---|---|
| 4.2599610 | 42.715224 | 31.903528 | 21.312271 |

TABLE 3
Pin Output

| Pad Number | Element |
|---|---|
| 1 | 1.4 |
| 2 | 1.1 |
| 3 | 1.2 |
| 4 | 1.3 |
| 5 | 2.4 |
| 6 | 2.3 |
| 7 | 2.2 |
| 8 | 2.1 |
| 9 | Substrate/Bulk Silicon |
| 10 | 3.4 |
| 11 | 3.3 |
| 12 | 3.2 |
| 13 | 3.1 |
| 14 | Common/Bottom |
| | Electrode/Substrate |
| 15 | 4.4 |
| 16 | 4.3 |
| 17 | 4.2 |
| 18 | 4.1 |
| 19 | Common/Bottom |
| | Electrode/Substrate |
| 20 | 5.4 |
| 21 | 5.3 |
| 22 | 5.2 |
| 23 | 5.1 |
| 24 | Common/Bottom |
| | Electrode/Substrate |
| 25 | 6.4 |
| 26 | 6.3 |
| 27 | 6.2 |
| 28 | 6.1 |
| 29 | Substrate/Bulk Silicon |
| 30 | 7.4 |
| 31 | 7.3 |
| 32 | 7.2 |
| 33 | 7.1 |
| 34 | Substrate/Bulk Silicon |
| 35 | 8.4 |
| 36 | 8.3 |
| 37 | 8.2 |
| 38 | 8.1 |
| 39 | 8.8 |
| 40 | 8.7 |
| 41 | 8.6 |
| 42 | 8.5 |
| 43 | Substrate/Bulk Silicon |
| 44 | 7.8 |
| 45 | 7.7 |
| 46 | 7.6 |
| 47 | 7.5 |
| 48 | Substrate/Bulk Silicon |
| 49 | 6.8 |
| 50 | 6.7 |
| 51 | 6.6 |
| 52 | 6.5 |
| 53 | Common/Bottom |
| | Electrode/Substrate |
| 54 | 5.8 |
| 55 | 5.7 |
| 56 | 5.6 |
| 57 | 5.5 |
| 58 | Common/Bottom |
| | Electrode/Substrate |
| 59 | 4.8 |
| 60 | 4.7 |
| 61 | 4.6 |
| 62 | 4.5 |
| 63 | Common/Bottom |
| | Electrode/Substrate |
| 64 | 3.8 |
| 65 | 3.7 |
| 66 | 3.6 |
| 67 | 3.5 |
| 68 | Substrate/Bulk Silicon |
| 69 | 2.8 |
| 70 | 2.7 |
| 71 | 2.6 |
| 72 | 2.5 |
| 73 | 1.6 |
| 74 | 1.7 |
| 75 | 1.8 |
| 76 | 1.5 |

### Calculation of Dimple Spacing

Calculation Based on Doubly Clamped Beam:

E=169·10⁹ (Pa) modulus of elasticity

h=2·10⁻⁶ (m) Height of cavity

t=3.5·10⁻⁶ (m) Thickness of structure

γ=0.2

$$( \frac{J}{{m}^{2}} )$$

Interfacial adhesion energy per unit area

l=600·10⁻⁶ (m) Distance between the two supports

$${N}_{p} = \frac{128 {Eh}^{2} {t}^{3}}{5 γ {l}^{4}}$$

### IN METERS!!!

Nₚ=0.029 (m)

### Calculations for Solution

### Resolution at High Point on Curve

$$H = 2 \times {10}^{- 6} \frac{V}{\sqrt{Hz}}$$

$$f = 2000 - 150$$

$${V}_{H} = \sqrt{{H}^{2} f}$$

$${V}_{H} = 2.8182 \times {10}^{- 4}$$

### Resolution at Low Point on Curve

$$L = 2 \times {10}^{- 7} \frac{V}{\sqrt{Hz}}$$

$$f = 2000 - 150$$

$${V}_{L} = \sqrt{{L}^{2} f}$$

$${V}_{L} = 2.8182 \times {10}^{- 5}$$

### Resolution at Each Point on Curve

mV=0.04 millivolt input from matlab script

High End

$${P}_{H} = \frac{{V}_{H}}{\frac{mV}{1000}}$$

$${P}_{H} = 7.045$$

$${X}_{H} = ( \frac{{P}_{H}}{4 \times {10}^{- 5}} )$$

$${X}_{H} = 1.761 \times {10}^{5}$$

$${Y}_{H} = 20 log ( {X}_{H} )$$

$${Y}_{H} = 105 dB SPL$$

Low End

$${P}_{L} = \frac{{V}_{L}}{\frac{mV}{1000}}$$

$${P}_{L} = 7.045$$

### Calculations for Maximum Deflection

### Resolution at the Low End

$$P = 30 \frac{µV}{\frac{2560 µV}{Pa}}$$

$$P \to \frac{3}{256} Pa$$

$$X = \frac{P}{20 μ Pa}$$

$$X \to 585.9375$$

$$Y = 20 log ( X )$$

$$Y = 55.357 dB SPL$$

### Max Deflection of Design at 150 dB at 5 kHz:

$${10}^{\frac{150}{20}} = 3.162 \times {10}^{7}$$

$$3.162 \times {10}^{7} \cdot 20 \times {10}^{- 6} = 632.4 Pa$$

$$632.4 ( \frac{0.193 \times {10}^{- 9}}{1} ) = 1.221 \times {10}^{- 7} or 121 nm$$

### Calculations for Wire Resistance and Capacitance

### Resistance of Trace:

$$R = \frac{rl}{w}$$

where:
R=resistance in ohms (Ω)
r=sheet resistance in ohms/square (Ω/sq)
l=length of wire
w=width of wire
   Sheet Resistance for Wiring Layers with the Average Sheet Resistance in Parenthesis:
Poly1=1−20(10) Ω/sq
Poly2=10−30(20) Ω/sq
Metal=0.05−0.07(0.06) Ω/sq

### Constants Defined:

$${r}_{1} = 10$$

$${r}_{2} = 20$$

$${r}_{M} = 0.06$$

$$l = 4382.58$$

$$w = 6$$

$${R}_{1} = \frac{{r}_{1} l}{w}$$

$${R}_{2} = \frac{{r}_{2} l}{w}$$

$${R}_{3} = \frac{{r}_{M} l}{w}$$

$$R = \frac{1}{{R}_{1}} + \frac{1}{{R}_{2}} + \frac{1}{{R}_{M}} = 0.023$$

### Example 2

### Additional Sensor Configurations

### Parylene Coating to Reduce Vent Hole Size

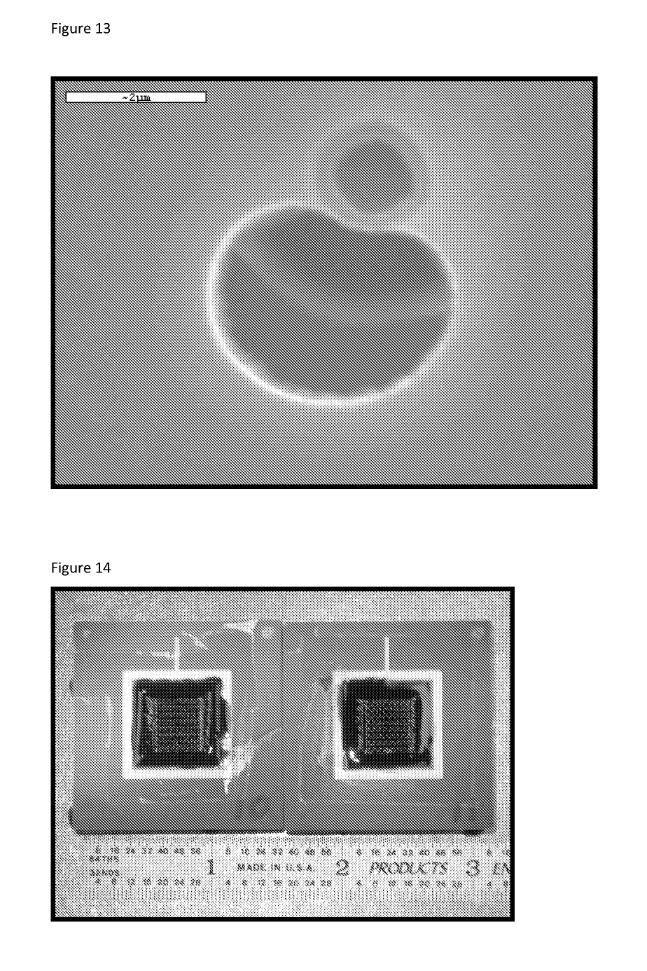

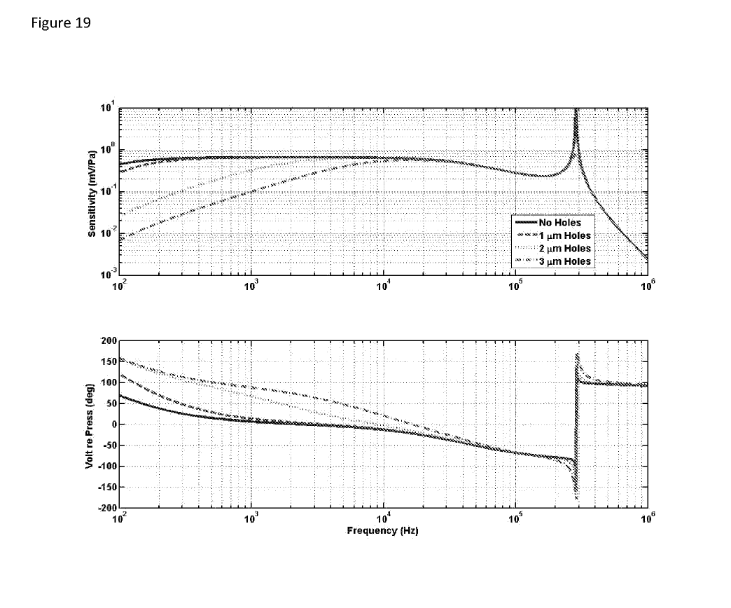

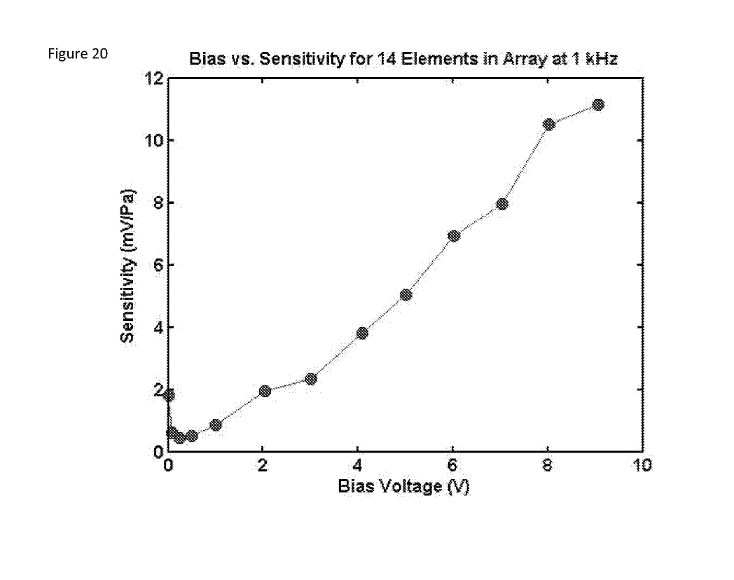

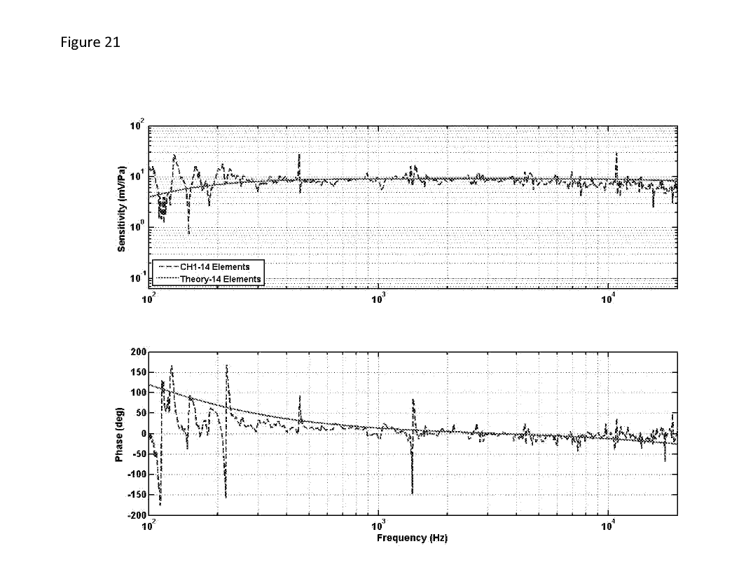

Various manufacturing variations are inherent to MEMS design, such as slight misalignment of structural layers, overetching of the silicon nitride layer, and variations in material properties from wafer to wafer. In the device described herein, the size of the vent holes in the diaphragm were not manufactured as designed. The vent hole sizes were irregular in shape (not circular as designed), as well as being larger than desired (about 2-3 microns in radius). This can be shown in FIG. 13. After extensive testing, this increase in vent hole size was determined to greatly decrease the low frequency response of the microphone. In order to close up the vent holes a deposition of Parylene-C (poly-para-xylylene) was developed. A deposition of 9.1 grams of dimer was used which yields an end result of a 1.7 micron layer of Parylene-C to coat the array along with the packaging. The basic physics of Parylene-C starts with a dimer in powder form. This powder is heated to 150° C. to change the physical state of the chemical to a vapor form. The dimer molecule is then placed in a pyrolysis furnace at 690° C. and the pressure is reduced to 0.5 ton to change the molecular structure to a monomer. Finally, the monomer is transformed to a polymer by entering a coating chamber at room temperature. This is the final coating that is applied to the sensor and electronics. The Parylene-C will electrically isolate the MEMS device from the environment and itself, as well as provide an excellent moisture barrier and thermal management for the sensor. After coating, the sensitivity results for the devices show, both experimentally and computationally, a broadband sensitivity level of 0.7 mV/Pa at bandpass output (See e.g., FIGS. 19-21).

### Packaging

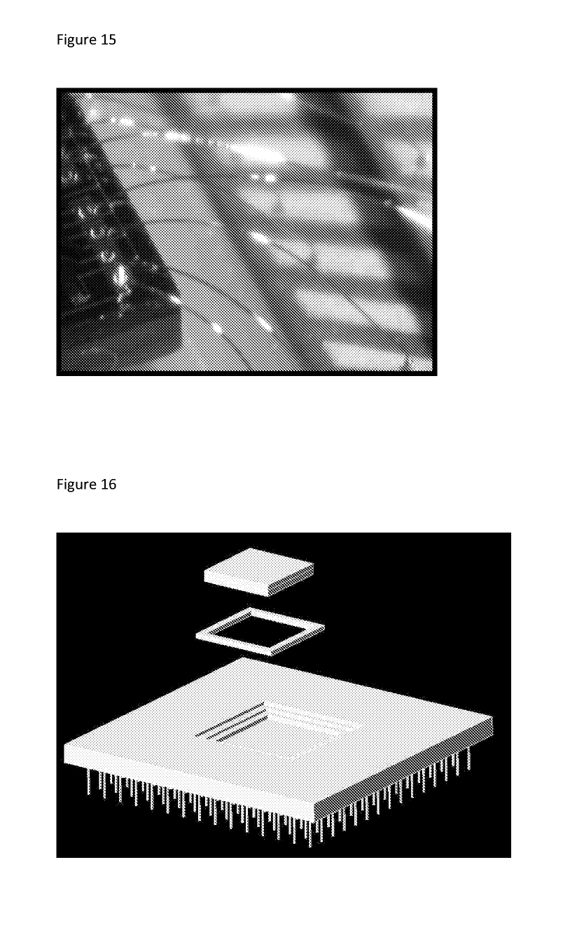

In order to apply the arrays for the measurement of aeroacoustics, it is preferred that the surface of the array be planar with the packaging. To this end, in some embodiments, the array is packaged as shown in FIG. 16. A glass spacer and polymer centering element are used to center the array and raise it to the correct height. The array is glued in place. The array is subsequently wirebonded to a ceramic hybrid pin grid array package (see FIGS. 14 and 15). Parylene-C coating in performed, and then the coated wirebonds are potted in epoxy for protection and to produce a planar surface, as shown in FIG. 14.

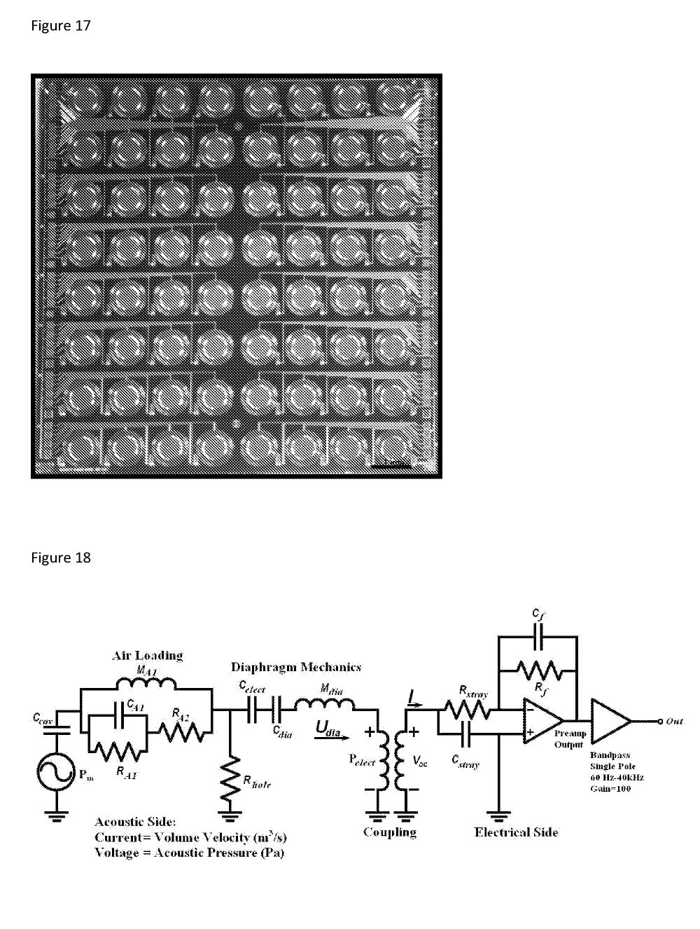

FIGS. 17-21 show sensitivity models, calibration curves and bias vs. sensitivity for exemplary arrays described herein.

### Computations

$${C}_{dia} = \frac{π {a}^{6}}{16 * 12} * \frac{1}{{D}_{eff}}$$

$${M}_{dia} = \frac{9 ( {ρ}_{1} {t}_{1} + {ρ}_{2} {t}_{2} )}{5 π {a}^{2}}$$

Deff is the effective bending stiffness of a thin laminate plate.

ρ₁ and t₁ are the density and thickness of the polysilicon layers and ρ₂ and t₂ are the density and thickness of the parylene-C layer

With the addition of:

$${D}_{eff} = {\sum }_{i = 1}^{I} \frac{{E}_{i}}{1 - {v}_{i}^{2}} ( \frac{{t}_{i}^{3}}{12} + {t}_{i} {y}_{i}^{2} )$$

$${y}_{c} = \frac{{\sum }_{i = 1}^{I} {x}_{i} ( \frac{{E}_{i}}{1 - {v}_{i}^{2}} )}{{\sum }_{i = 1}^{I} \frac{{E}_{i}}{1 - {v}_{i}^{2}}}$$

$${y}_{i} = {x}_{n} - {y}_{c}$$

Ending with:

P=N·V_{ac}

I=N·U_{dia}

Table 1 shows performance of pressure sensor arrays.

TABLE 1
Performance of pressure sensor array.

| Performance Parameter | Device Characteristics |
|---|---|
| Sensor Chip Size | 1.01 cm × 1.01 cm |
| Number of Elements | 64 |
| Individual Sensor Diameter | 0.6 mm |
| Sensor Center-to-Center Spacing (Pitch) | 1.2625 mm |
| Sensor Bandwidth | 430 kHz |
| Sensitivity of Individual Element | 0.61 mV/Pa @ 1 kHz |
| Sensitivity of Entire Array | 39 mV/Pa @ 1 kHz |
| Center Displacement of Element | 0.06 nm/Pa² @ 1 kHz |
| Low Frequency Rolloff | below 100 Hz |
| Capacitance of Each Element | 120 pF |

All publications and patents mentioned in the above specification are herein incorporated by reference as if expressly set forth herein. Various modifications and variations of the described method and system of the invention will be apparent to those skilled in the art without departing from the scope and spirit of the invention. Although the invention has been described in connection with specific preferred embodiments, it should be understood that the invention as claimed should not be unduly limited to such specific embodiments. Indeed, various modifications of the described modes for carrying out the invention that are obvious to those skilled in relevant fields are intended to be within the scope of the following claims.

We claim:

1. A composition, comprising an array of MEMS microphones, wherein said array comprises at least 10 MEMS microphones on a single chip.

2. The composition of claim 1, wherein said array comprises at least 64 MEMS microphones on a single chip.

3. The composition of claim 1, wherein said array comprises at least 100 MEMS microphones on a single chip.

4. The composition of claim 1, wherein each of said MEMS microphones is between 10 μm and 1000 μm in diameter.

5. The composition of claim 1, wherein each of said MEMS microphones is approximately 600 μm in diameter.

6. The composition of claim 1, wherein said array has a center to center pitch of between 0.5 and 1.5 mm.

7. The composition of claim 1, wherein said array has a center to center pitch of approximately 1.2625 mm.

8. The composition of claim 1, wherein each of said MEMS microphones comprises a silicon substrate with multiple coating layers.

9. The composition of claim 8, wherein said layers comprise one or more layers selected from the group consisting of nitride layers, polysilicon layers, polymer layers, metal layers, anchor layers, paralene layers, and dimple layers.

10. The composition of claim 9, wherein said array is coated in parylene-C.

11. The composition of claim 9, wherein said dimple layer comprises corrugated circles.

12. The composition of claim 8, wherein one or more of said layers comprise holes.

13. The composition of claim 1, wherein said array comprises electronic components.

14. The composition of claim 13, wherein said electronics are located off of said array chip.

15. The composition of claim 1, wherein said array comprises guard bands.

16. The composition of claim 1, wherein said array comprises alignment markers.

17. The composition of claim 1, wherein said array comprises front venting.

18. The composition of claim 1, wherein said composition comprises a plurality of array chips assembled end to end.

19. A method of measuring pressure fluctuations, comprising: contacting a composition, comprising an array of MEMS microphones, wherein said array comprises at least 10 MEMS microphones on a single chip with a turbulent boundary layer under conditions such that said composition measures pressure fluctuations below the turbulent boundary layer.

20. The method of claim 19, wherein said composition is located in a location selected from the group consisting of a wind tunnel and an aircraft in flight.

21. A composition, comprising an array of MEMS microphones, wherein said array comprises an array of MEMS microphones on a single chip, and wherein said array has a center to center pitch of between 0.5 and 1.5 mm.

22. The composition of claim 21, wherein said array has a center to center pitch of between 0.5 and 1.5 mm.

23. The composition of claim 21, wherein said array has a center to center pitch of approximately 1.2625 mm.

24. A composition, comprising an array of MEMS microphones, wherein said array comprises an array of MEMS microphones on a single chip, and wherein each of said MEMS microphones is between 10 μm and 1000 μm in diameter.
